(19) United States
(12) Patent Application Publication
(10) Pub. No.: US 2022/0399206 A1
(43) Pub. Date: Dec. 15, 2022

(54) METHOD FOR BUILDING CONDUCTIVE THROUGH-HOLE VIAS IN GLASS SUBSTRATES

(71) Applicant: V-FINITY INC., Saratoga, CA (US)

(72) Inventor: Heng Liu, Sunnyvale, CA (US)

(21) Appl. No.: 17/724,317

(22) Filed: Apr. 19, 2022

Related U.S. Application Data
(60) Provisional application No. 63/209,902, filed on Jun. 11, 2021.

(51) Int. Cl. H01L 21/48; H01L 21/027; H01L 23/498; H01L 23/48

(52) U.S. Cl. CPC H01L 21/486; H01L 21/0275; H01L 23/49827; H01L 23/481

(57) ABSTRACT

A method for forming a conductive through-hole-via in a glass substrate comprises: placing circuitry on a first surface of the glass substrate such that a section of the glass substrate on the first surface is exposed; applying a coating to the first surface covering both the circuitry and the exposed section of the first surface; removing the coating over the exposed section; inducing structural damage to at least a portion of the exposed section with laser radiation; and wet etching away the at least a portion of the exposed section to form a via.

### CROSS-REFERENCE TO RELATED APPLICATIONS

This application claims priority to and incorporates by reference U.S. Provisional Patent Application No. 63/209,902 filed Jun. 11, 2021.

### TECHNICAL FIELD

This disclosure related to vias and more particularly, but not exclusively, to building conductive vias in through glass substrates.

### BACKGROUND

Prefabricated vias on glass substrate (before placement of circuitry) may cause glass breakage or contamination to the tools used for the fabrication process. For example, glass with a Through-Hole Via (THV) may have residual stress that could lead to glass breakage during the mechanical transfer at or between process steps; metal in the conductive material used to fill the THV can be a source of contamination to the polysilicon (Low Temperature Polycrystal Silicon (LTPS)) or amorphous silicon Thin Film Transistor (TFT) during the deposition of these materials.

### BRIEF SUMMARY

A method for forming a conductive through-hole-via in a glass substrate comprises: placing circuitry on a first surface of the glass substrate such that a section of the glass substrate on the first surface is exposed; applying a coating to the first surface covering both the circuitry and the exposed section of the first surface; removing the coating over the exposed section; inducing structural damage to at least a portion of the exposed section with laser radiation; and wet etching away the at least a portion of the exposed section to form a via.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a method of building conductive Through-Hole-Vias in glass substrates in accordance with an example.

FIG. 2 illustrates a method of building a Through-Hole-Via in glass substrates in accordance with an example.

FIG. 3 illustrates a method of building a Through-Hole-Via in glass substrates in accordance with an example.

FIG. 4 illustrates a method of adding a conductor to a Through-Hole-Via in glass substrates in accordance with an example.

FIG. 5 illustrates a method of adding a conductor to a Through-Hole-Via in glass substrates in accordance with an example.

FIG. 6 illustrates a method of adding a conductor to a Through-Hole-Via in glass substrates in accordance with an example.

### DETAILED DESCRIPTION

In order to mitigate manufacturing issues in glass substrates, an example embodiment forms THV or conductive THV after the circuitry has been placed onto the glass substrate.

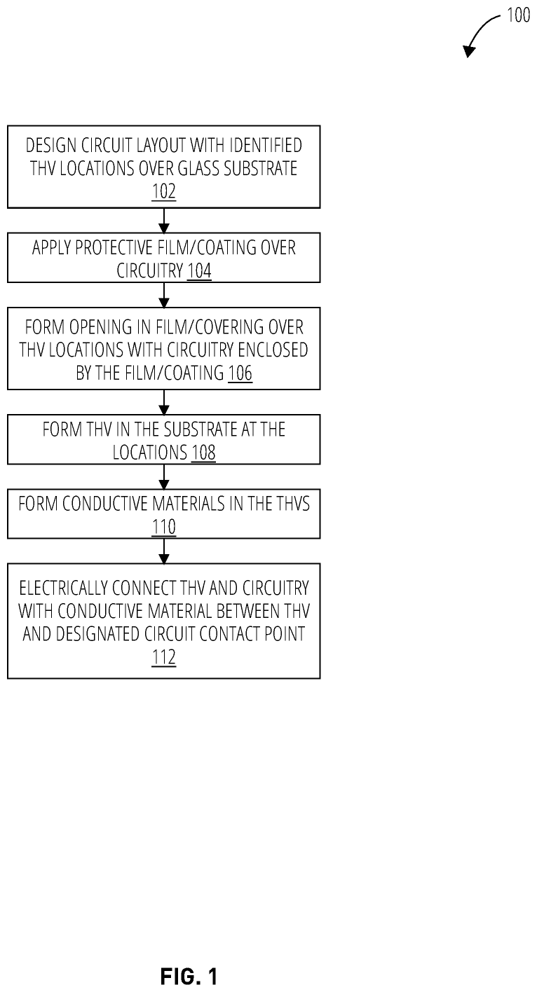

FIG. 1 illustrates a method 100 of building conductive Through-Hole-Vias in glass substrates in accordance with an example. In block 102, circuit layout is designed with identified THV locations over glass substrate. In block 104, protective film/coating is applied over circuitry. In block 106, an opening in film/covering over THV locations with circuitry enclosed by the film/coating is formed. The THV location is designed to avoid any effect on Thin Film Transistor (TFT) circuitry during the THV formation process. For example, the THV location can have no circuitry and is in a safe distance from the circuitry. The THV formation process may have heat generated that could affect the performance of the circuitry. In block 108, THV in the substrate at the locations is formed. In block 110, conductive materials in the THVs are formed. In block 112, the THV and circuitry are electrically connected with conductive material between THV and designated circuit contact point.

The substrate can be used to form LED or OLED over the circuitry (e.g., active matrix), and form driver circuitry and/or flexible printed circuits (FPCs) over the back of the substrate for a display module. The substrate can also be used as glass interposer and for 3D packaging where multiple devices such as semiconductor chips can be mounted on both top and bottom sides of the substrate and electrically connected by the THV.

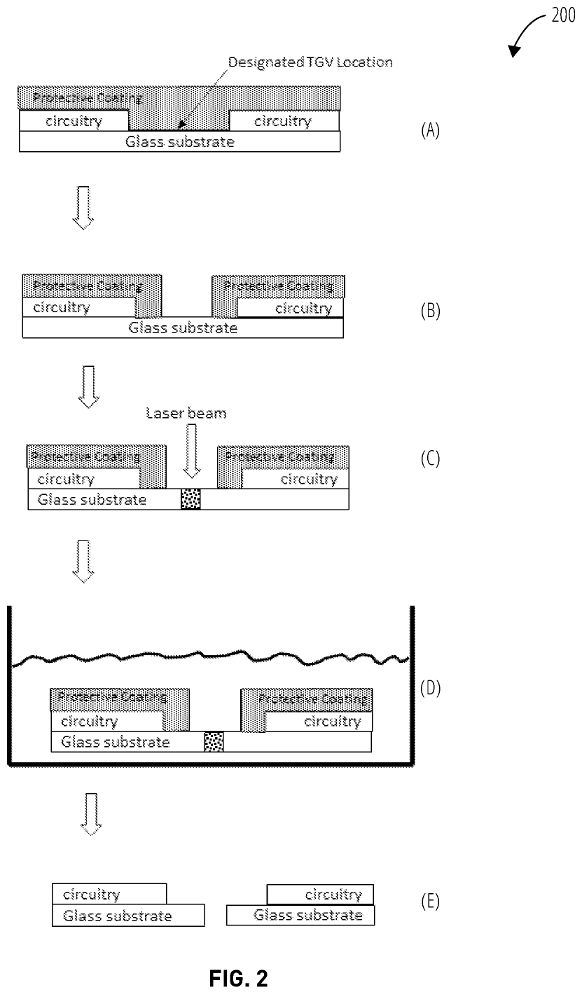

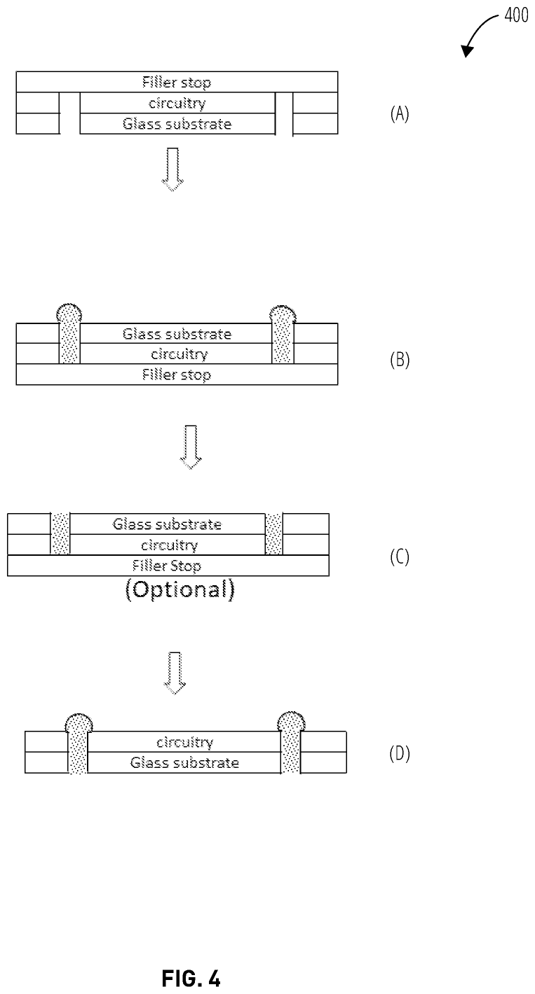

FIG. 2 illustrates a method 200 of building a Through-Hole-Via in glass substrates in accordance with an example. At A, protective film/coating is applied over both circuitry and glass substrate. The protective coating can be photoresist that can be patterned by photolithographic method or can be an acid-resist film patterned by laser drill holes in the film. Next, at B, holes in protective coating are opened at the designated TGV location. This can be done by photolithography or by laser beam irradiation. Next, at C, the film opening is laser irradiated (e.g., via laser induced deep etching (LIDE)) to induce structural damage in glass at the designated locations. At D, the damaged glass area is wet etched away in etching solution (can be hydrofluoric acid (HF)-based for example). Protective coating can resist etching solution such that the etching rate of un-damaged glass area is much slower than damaged area. At E, the protective film is removed and the TGV substrate is ready for conductive material fill process as shown and described below in conjunction with FIG. 4.

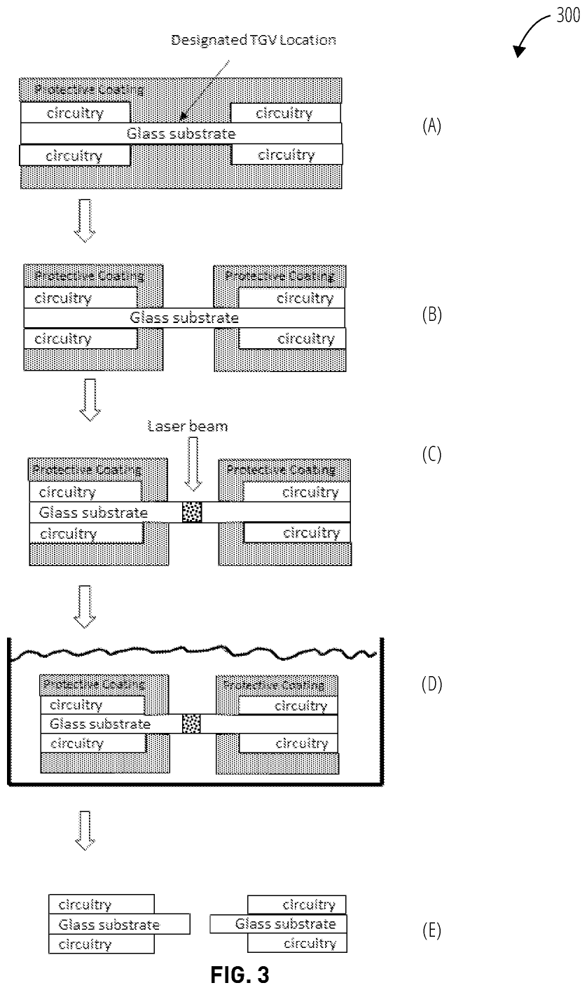

FIG. 3 illustrates a method 300 of building a Through-Hole-Via in glass substrates in accordance with an example. In this example, circuitry is located on first and second opposing sides of a glass substrate. At A, protective film/coating is applied on both sides of circuit and glass substrate. Protective coating can be photoresist that can be patterned by photolithographic method or can be an acid-resist film patterned by laser drill holes in the film. At B, holes are opened in protective coating at the designated TGV location. This can be done by photolithography or by laser beam irradiation. Next, at C, laser radiation is radiated onto the film opening and induce structural damage in glass at the designated locations (e.g., via LIDE). Next, at D, damaged glass area is wet etched away in etching solution (can be HF-based). Protective coating can be resistant to etching solution such that the etching rate of undamaged glass area is slower than damaged area. At E, protective film is removed and the TGV substrate is ready for conductive material fill process, e.g., FIG. 4, etc.

FIG. 4 illustrates a method 400 of adding a conductor to a Through-Hole-Via in glass substrates in accordance with an example. Continuing from the method 200, at A, filler stop is applied over all the TGV on circuit side. Filler stop can a temporary layer of solid film such as polyimide (PI). Next, at B, conductive paste/ink is filled in the via under vacuum. The fill method can be screen printing or inject printing, etc. Vacuum prevents air in the via that could prevent the filler material from going into the via. Optionally, at C, the amount and shape of the excess paste/ink sometimes is not easy to control. It maybe necessary to have the excess removed and use the well defined solder paste screen printing process to create well defined connection to the circuitry. Accordingly, after curing the paste/ink, excessive paste/ink extruding the substrate can be removed. At D, filler stop is removed. Solder is screen printed and reflowed to electrically connect the filled TGV to the circuitry (e.g., TFT circuitry such as active matrix or passive matrix for displays).

Conductive paste/ink material can be epoxy based Cu or Ag paste; or solder paste such as SnAg. When epoxy based is used, the paste/ink usually require oven bake to cure. If solder paste is used, a high temperature re-flow (200-400 degrees C.) is required to form joints.

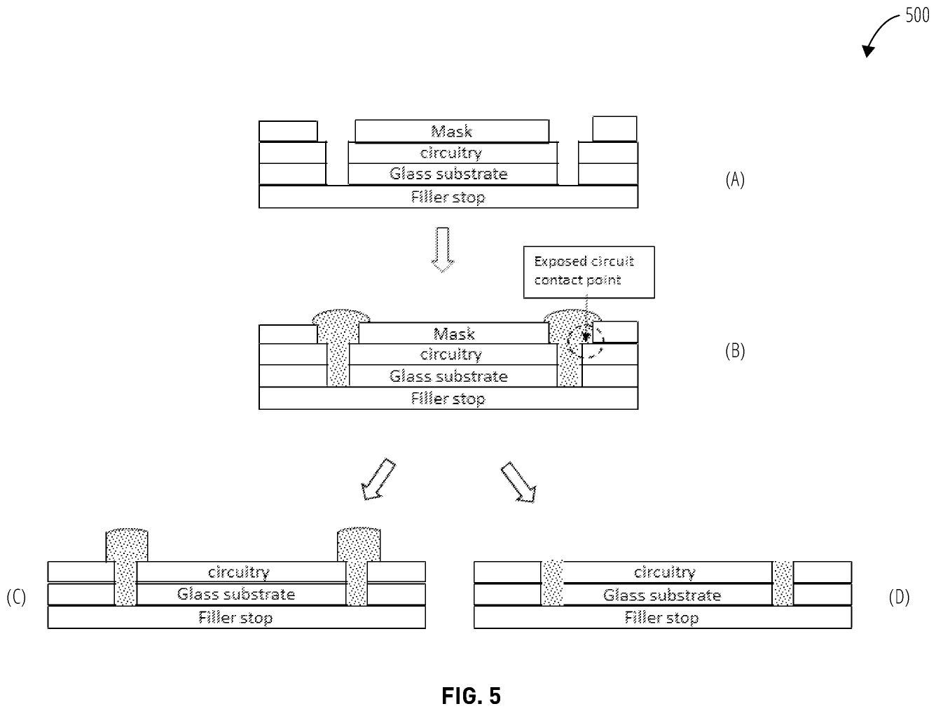

FIG. 5 illustrates a method 500 of adding a conductor to a Through-Hole-Via in glass substrates in accordance with an example. Continuing from the method 200, at A, filler stop is applied on one side of the glass substrate and masking the other side over the circuitry with openings larger than the TGV to expose the circuit contact points that need to be connected to the TGV. At B, conductive paste/ink is vacuum screen printed so that it covers the exposed circuit contact points. At C and D, after paste/ink is cured the mask is removed. Note the paste print over the mask could break off as shown in C, or can break off at the substrate surface level as shown in D.

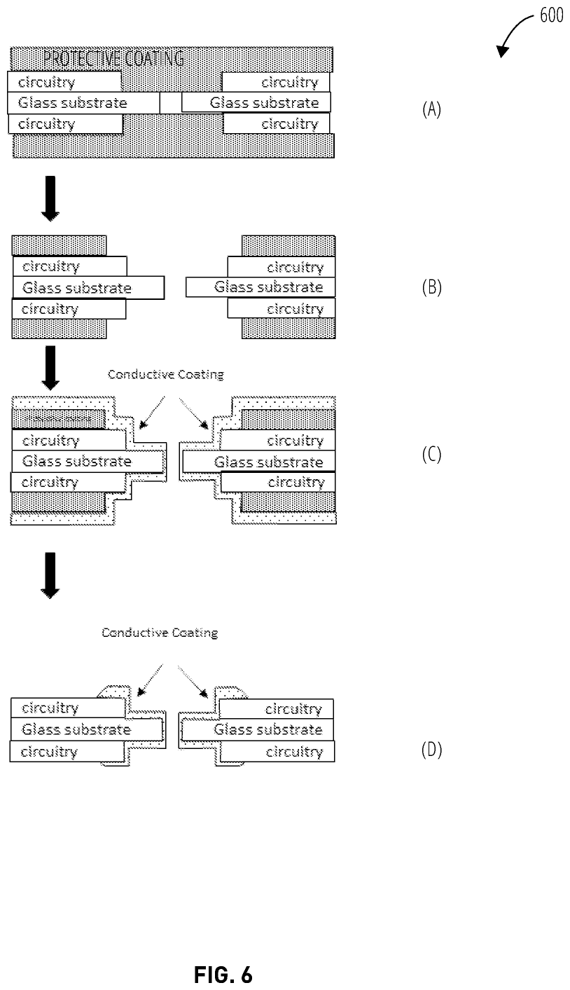

FIG. 6 illustrates a method 600 of adding a conductor to a Through-Hole-Via in glass substrates in accordance with an example. Continuing from the method 300, at A, a protective coating is formed on both sides of the circuit-glass substrate with TGV. Next, at B, openings are formed over the TGV area to expose part of the circuitry to be connected. At C, conductive coating is formed to electrically connect circuitry on both sides of the glass substrate. At D, the protective coating is removed. The conductive material can be metal, Indium tin oxide (ITO), conductive paste/ink. Metal coating can be formed by electroplating or electroless plating. Conductive paste/ink can be applied by screen printing such that the TGV can be completely filled or partially filled.

In view of the disclosure above, various examples are set forth below. It should be noted that one or more features of an example, taken in isolation or combination, should be considered within the disclosure of this application.

1. A method for forming a conductive through-hole-via in a glass substrate, comprising:

placing circuitry on a first surface of the glass substrate such that a section of the glass substrate on the first surface is exposed;
applying a coating to the first surface covering both the circuitry and the exposed section of the first surface;
removing the coating over the exposed section;
inducing structural damage to at least a portion of the exposed section with laser radiation; and wet etching away the at least a portion of the exposed section to form a via.

2. The method of example 1, wherein the removing the coating over the exposed section is performed with photolithography or laser beam irradiation.

3. The method of any of the preceding examples, further comprising:

placing second circuitry on a second surface of the glass substrate such that a second section of the glass substrate on the second surface is exposed, the second surface opposing the first surface; and
applying coating to the second surface covering both the second circuitry and the second exposed section of the second surface.

4. The method of any of the preceding examples, further comprising:

placing filler stop on the first surface;
in a vacuum, filling the via with a conductor; and
curing the conductor.

5. The method of any of the preceding examples, wherein the conductive coating includes a metal plating and the applying the conductive coating includes electroplating or electroless plating.

6. The method of any of the preceding examples, wherein the conductive coating includes indium tin oxide.

7. The method of any of the preceding examples, wherein the conductive coating includes an epoxy based paste and the applying the conductive coating include vacuum screen printing.

8. The method of any of the preceding examples, further comprising;

applying a second coating to the first and second surfaces;
forming openings in the via area exposing a portion of the first and second circuitry to be connected;
forming conductive coating to electrically connect first and second circuitries.

9. The method of any of the preceding examples, further comprising:

placing filler stop on the first surface;
in a vacuum, filling the via with a conductor;
curing the conductor;
removing the filler stop; and
electrically connecting the cured conductor in the via with the circuitry.

10. The method any of the preceding examples, further comprising removing excess conductor that extends out of the substrate.

11. The method of any of the preceding examples, wherein the conductor includes an epoxy-based paste.

12. The method of any of the preceding examples, wherein the conductor includes a solder paste.

13. The method of any of the preceding examples, wherein the applying the coating includes applying photoresist via photolithography.

14. The method of any of the preceding examples, wherein the applying the coating includes applying an acid-resist film patterned by laser drill holes.

15. The method of any of the preceding examples, wherein the wet etching uses hydrofluoric acid and the coating is resistant to the acid.

16. The method of any of the preceding examples, wherein the circuitry includes active matrix display circuitry.

17. The method of any of the preceding examples, wherein the circuitry includes passive matrix display circuitry.

18. The method any of the preceding examples, further comprising:

placing filler stop on a second surface of the substrate opposing the first surface;
applying a mask over the circuitry leaving an exposed section of mask having a width greater than a width of the via;
in a vacuum, filling the via with a conductor;
vacuum screen printing the conductor over exposed circuit contact points of the circuitry;
curing the conductor; and
removing the filler stop.

19. The method of any of the preceding examples, further comprising removing any remaining coating.

20. A glass substrate, comprising:

a first circuitry on a first surface and a second circuitry on a second surface;
the second surface opposing the first surface;
at least one through-glass-via electrically connecting the first and second circuitry;
wherein the at least one through-glass-via is made after the circuitries are made over the glass substrate per any of the preceding examples.

What is claimed is:

1. A method for forming a conductive through-hole-via in a glass substrate, comprising:
placing circuitry on a first surface of the glass substrate such that a section of the glass substrate on the first surface is exposed;
applying a coating to the first surface covering both the circuitry and the exposed section of the first surface;
removing the coating over the exposed section;
inducing structural damage to at least a portion of the exposed section with laser radiation; and
wet etching away the at least a portion of the exposed section to form a via.

2. The method of claim 1, wherein the removing the coating over the exposed section is performed with photolithography or laser beam irradiation.

3. The method of claim 1, further comprising:
placing second circuitry on a second surface of the glass substrate such that a second section of the glass substrate on the second surface is exposed, the second surface opposing the first surface; and
applying coating to the second surface covering both the second circuitry and the second exposed section of the second surface.

4. The method of claim 3, further comprising:
placing filler stop on the first surface;
in a vacuum, filling the via with a conductor; and
curing the conductor;

5. The method of claim 4, wherein the conductive coating includes a metal plating and the applying the conductive coating includes electroplating or electroless plating.

6. The method of claim 4, wherein the conductive coating includes indium tin oxide.

7. The method of claim 4, wherein the conductive coating includes an epoxy based paste and the applying the conductive coating include vacuum screen printing.

8. The method of claim 3, further comprising;
applying a second coating to the first and second surfaces;
forming openings in the via area exposing a portion of the first and second circuitry to be connected;
forming conductive coating to electrically connect first and second circuitries.

9. The method of claim 1, further comprising:
placing filler stop on the first surface;
in a vacuum, filling the via with a conductor;
curing the conductor;
removing the filler stop; and
electrically connecting the cured conductor in the via with the circuitry.

10. The method of claim 9, further comprising removing excess conductor that extends out of the substrate.

11. The method of claim 9, wherein the conductor includes an epoxy-based paste.

12. The method of claim 9, wherein the conductor includes a solder paste.

13. The method of claim 1, wherein the applying the coating includes applying photoresist via photolithography.

14. The method of claim 1, wherein the applying the coating includes applying an acid-resist film patterned by laser drill holes.

15. The method of claim 1, wherein the wet etching uses hydrofluoric acid and the coating is resistant to the acid.

16. The method of claim 1, wherein the circuitry includes active matrix display circuitry.

17. The method of claim 1, wherein the circuitry includes passive matrix display circuitry.

18. The method of claim 1, further comprising:
placing filler stop on a second surface of the substrate opposing the first surface;
applying a mask over the circuitry leaving an exposed section of mask having a width greater than a width of the via;
in a vacuum, filling the via with a conductor;
vacuum screen printing the conductor over exposed circuit contact points of the circuitry;
curing the conductor; and
removing the filler stop.

19. The method of claim 1, further comprising removing any remaining coating.

20. A glass substrate, comprising:
a first circuitry on a first surface and a second circuitry on a second surface;
the second surface opposing the first surface;
at least one through-glass-via electrically connecting the first and second circuitry;
wherein the at least one through-glass-via is made after the circuitries are made over the glass substrate.
